(19) United States
(12) Patent Application Publication
(10) Pub. No.: US 2026/0190799 A1
(43) Pub. Date: Jul. 2, 2026

(54) DISPLAY DEVICE

(71) Applicant: LG DISPLAY CO., LTD., Seoul (KR)

(72) Inventor: Keum Young OH, Paju-si (KR)

(73) Assignee: LG DISPLAY CO., LTD., Seoul (KR)

(21) Appl. No.: 19/312,038

(22) Filed: Aug. 27, 2025

(30) Foreign Application Priority Data
Jan. 2, 2025 (KR) 10-2025-0000309

(51) Int. Cl. H10K 59/80; G02F 1/13; G09G 3/3233; H10K 59/35

(52) U.S. Cl. CPC H10K 59/875; G02F 1/1323; G09G 3/3233; H10K 59/353; H10K 59/8792; H10K 59/8793; G09G 2310/08; G09G 2354/00

(57) ABSTRACT

A display device can include a display area including a first display area and a second display area, a light-emitting element layer disposed in the display area, the light-emitting element layer including a first light-emitting element and a second light-emitting element, and a film layer disposed on the light-emitting element layer. Also, the film layer includes a light control member disposed above the first light-emitting element, the first light-emitting element is configured to emit light at a first viewing angle in a first mode, and the second light-emitting element configured to emit light at a second viewing angle in second mode, the second viewing angle being wider than the first viewing angle.

### CROSS-REFERENCE TO RELATED APPLICATION

This application claims priority to and the benefit of Korean Patent Application No. 10-2025-0000309, filed in the Republic of Korea on Jan. 2, 2025, the entirety of which is incorporated herein by reference into the present application.

### BACKGROUND

### 1. Field of the Invention

The present specification relates to a display device.

### 2. Discussion of Related Art

Display devices are applied to various electronic devices such as TVs, mobile phones, laptop computers, and tablets.

The display devices include organic light-emitting display (OLED) devices, which are self-emissive, liquid crystal display (LCD) devices, which require a separate light source, and the like.

Among the display devices, the OLED devices are self-emissive devices that have significant advantages such as quick response time, high luminous efficiency, high luminance, and a wide viewing angle. In particular, the OLED devices can be formed on flexible substrates and are capable of operating at lower voltages, consuming relatively less power, and providing excellent color expression compared to plasma display panels (PDPs) or inorganic electroluminescent displays.

In displays using OLED devices (e.g., such as automotive displays), research is being conducted on a method of controlling a viewing angle by selectively switching a single screen between a narrow viewing angle and a wide viewing angle. However, there is a problem in that the viewing angle cannot be adjusted as desired in such technology.

For example, existing displays have an inability to dynamically alter the viewing angle. For example, user cannot easily share content with others on a private display, nor can they protect sensitive information on a public one.

Thus, a need exists for a more versatile display technology that can adapt to the user's changing needs, offering both a narrow, private viewing mode and a wide, shareable one in a single device.

### SUMMARY OF THE DISCLOSURE

An object of the present invention is to solve the above-mentioned needs and/or problems.

The present specification is directed to providing a display device capable of providing both a wide viewing angle mode and a narrow viewing angle mode using a single display device.

Objectives according to embodiments of the present specification are not limited to the above-described objectives, and other objectives that are not described herein will be apparently understood by those skilled in the art from the following description.

According to an aspect of the present invention, there is provided a display device including a display area including a first display area and a second display area, a light-emitting element layer including a first light-emitting element and a second light-emitting element, which are disposed in the display area, and a film layer disposed on the light-emitting element layer, IN in which a light control member is disposed in the film layer disposed above the first light-emitting element, the first light-emitting element emits light at a first viewing angle in a first mode, and the second light-emitting element emits light at a second viewing angle that is wider than the first viewing angle in a second mode.

Specific details according to various examples of the present specification, other than the solutions mentioned above, are included in the description and the drawings below.

### BRIEF DESCRIPTION OF THE DRAWINGS

The above and other objects, features, and advantages of the present invention will become more apparent to those of ordinary skill in the art by describing example embodiments thereof in detail with reference to the accompanying drawings, which are briefly described below.

FIG. 1 is a block diagram illustrating a display device according to an embodiment of the present specification.

FIG. 2 is a circuit diagram illustrating a pixel circuit according to an embodiment of the present specification.

FIG. 3 is an enlarged plan view of region P in FIG. 1 according to an embodiment of the present specification.

FIG. 4 is an enlarged plan view of region P in FIG. 1 when a first mode is driven according to an embodiment of the present specification.

FIGS. 5A and 5B are cross-sectional views taken along line I-I′ of FIG. 4 according to one embodiment of the present specification.

FIG. 6 is an enlarged plan view of region P of FIG. 1 when a 2-1 mode is driven according to an embodiment of the present specification.

FIG. 7 is an enlarged plan view of region P of FIG. 1 when a 2-2 mode is driven according to another embodiment of the present specification.

FIGS. 8 and 9 are cross-sectional views taken along line II-II′ of FIG. 6 according to an embodiment of the present specification.

### DETAILED DESCRIPTION OF THE EMBODIMENTS

Advantages and features of the present invention and implementation methods thereof will be clarified through the following embodiments described with reference to the accompanying drawings. However, the present invention is not limited to the embodiments described below and can be embodied with a variety of different modifications. The embodiments are merely provided to allow those skilled in the art to completely understand the scope of the present invention, and the present invention is defined only by the scope of the claims.

The figures, dimensions, ratios, angles, numbers, and the like disclosed in the drawings for describing the embodiments of the present invention are merely illustrative and thus the present invention is not limited to matters illustrated in the drawings. Throughout the specification, like reference numerals refer to substantially like components. Further, in describing the present invention, detailed descriptions of well-known technologies will be omitted when it is determined that they can unnecessarily obscure the gist of the present invention.

Terms such as “including,” “having,” and “composed of” used herein are intended to allow other elements to be added unless the terms are used with the term “only.” Any references to the singular can include the plural unless expressly stated otherwise.

Components are interpreted to include an ordinary error range even if not expressly stated.

When positional or interconnection relationships between two parts is described as “on,” “above,” “below,” “over,” “under,” and “next to,” and the like, one or more parts can be interposed therebetween unless the term “immediately” or “directly” is used in the expression.

When the temporal order relationship is described using the terms such as “after,” “subsequent to,” “next,” “before,” and the like, a situation that is not continuous can be included unless the term “immediately” or “directly” is used.

Although the terms first, second, and the like are used to distinguish the components, the functions or structures of these components are not limited by the ordinal number before the component or the name of the component.

The following embodiments can be partially or entirely bonded to or combined with each other and can be interoperated and performed in technically various ways. Each of the embodiments can be independently operable with respect to each other and can be implemented together in related relationships. Also, the term “can” used herein includes all meanings and definitions of the term “may.”

In a display device of the present invention, a pixel circuit and a gate driving circuit can include a plurality of transistors. The transistors can be oxide thin-film transistors (TFTs) including an oxide semiconductor, or low-temperature polysilicon (LTPS) TFTs including LTPS.

The transistors are three-electrode elements each including a gate, a source, and a drain. The source is an electrode that provides carriers to the transistor. The carriers in the transistor start to flow from the source. The drain is an electrode through which the carriers are discharged from the transistor to the outside. In the transistor, carriers flow from the source to the drain. In the situation of an n-channel transistor, carriers are electrons, and thus a source voltage is lower than a drain voltage so that the electrons flow from the source to the drain. In the n-channel transistor, current flows from the drain to the source. In the situation of a p-channel transistor, carriers are holes, and thus a source voltage is higher than a drain voltage so that the holes flow from the source to the drain. In the p-channel transistor, since the holes flow from the source to the drain, current flows from the source to the drain. It should be noted that the source and the drain of the transistor are not fixed in position. For example, the source and the drain are interchangeable depending on the applied voltage. Accordingly, the present invention is not limited by the source and the drain of the transistor. In the following description, the source and the drain of the transistor will be referred to as a first electrode and a second electrode.

A gate signal can swing between a gate-on voltage and a gate-off voltage. The transistor is turned on in response to the gate-on voltage and turned off in response to the gate-off voltage. In the situation of an n-channel transistor, the gate-on voltage can be a gate-high voltage VGH, and the gate-off voltage can be a gate-low voltage VGL. In the situation of a p-channel transistor, the gate-on voltage can be a gate-low voltage VGL, and the gate-off voltage can be a gate-high voltage VGH.

Hereinafter, various embodiments of the present invention will be described in detail with reference to the accompanying drawings.

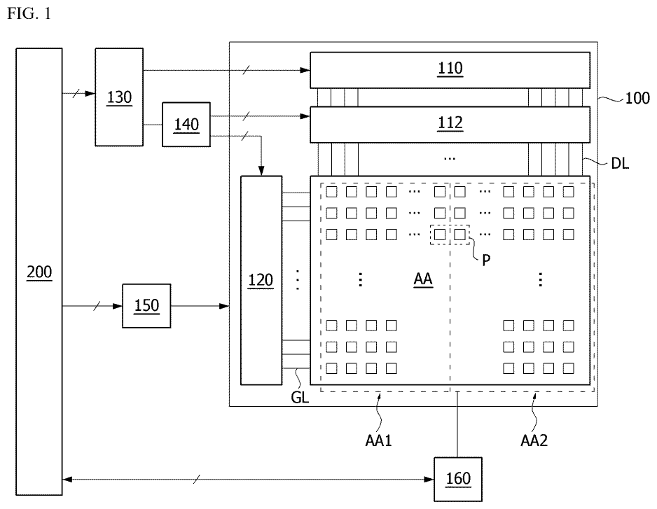

FIG. 1 is a block diagram illustrating a display device according to one embodiment of the present specification.

Referring to FIG. 1, the display device according to the embodiment of the present invention includes a display panel 100, a display panel driving circuit configured to write pixel data to display pixels of the display panel 100, and a power supply 150 configured to generate power for driving the display pixels and the display panel driving circuit.

The display panel 100 can be a panel with a rectangular-shaped structure having a length in an X-axis direction, a width in a Y-axis direction, and a thickness in a Z-axis direction. The display panel 100 can be implemented as a non-transmissive display panel or a transmissive display panel. The transmissive display panel is applicable to a transparent display device in which an image is displayed on a screen and a real background object is visible. The display panel 100 can be manufactured as a flexible display panel.

A display area AA of the display panel 100 can include a pixel array configured to display an input image. The display area AA can be disposed into a first display area AA1 and a second display area AA2. The pixel array can include a plurality of data lines DL, a plurality of gate lines GL intersecting the data lines DL, and the display pixels disposed in a matrix form. The display panel 100 can further include power lines commonly connected to the display pixels. The data lines DL can be formed to extend in a first direction, for example, in the X-axis direction. The gate lines GL can be formed to extend in a second direction, for example, in the Y-axis direction, and can intersect the data lines DL. The power lines are connected to constant voltage nodes of pixel circuits and supply a constant voltage necessary for driving display pixels P to the display pixels P.

Each of the display pixels P can be divided into a red sub-pixel, a green sub-pixel, and a blue sub-pixel for color implementation (e.g., or further include a white sub-pixel). Each of the sub-pixels can include the pixel circuit for driving a light-emitting element. Each of the pixel circuits is connected to the data lines, the gate lines, and the power lines.

The light-emitting element can be implemented as an organic light-emitting diode (OLED). The light-emitting element can include an anode, a cathode, and an organic compound layer formed therebetween. The organic compound layer can include a hole injection layer HIL, a hole transport layer HTL, an emission layer, an electron transport layer ETL, and an electron injection layer EIL, but embodiments of the present disclosure are not limited thereto. When a voltage is applied to the anode and the cathode of the light-emitting element, holes passing through the hole transport layer HTL and electrons passing through the electron transport layer ETL move to the emission layer to form excitons. At this time, visible light can be emitted from the emission layer. Each of the light-emitting elements can be implemented in a tandem structure in which a plurality of emission layers are stacked. The light-emitting elements of the tandem structure can improve the luminance and lifetime of the display pixel.

Pixel data of an input image can be written to the display pixels P in the display area of the display panel 100, so that the input image can be displayed on the display area of the display panel 100.

The power supply 150 can generate a direct current (DC) voltage (or a constant voltage) for driving the pixel array and the display panel driving circuit of the display panel 100 by using a DC-DC converter. The DC-DC converter can include a charge pump, a regulator, a buck converter, a boost converter, and the like. The power supply 150 can adjust the level of a DC input voltage received from a host system 200 and output a gamma reference voltage (VGMA), the constant voltage commonly applied to the display pixels P, the gate-on voltage, the gate-off voltage, and the like. The gamma reference voltage is supplied to a data driver 110. A dynamic range of a data voltage output from the data driver 110 is determined by a voltage range of the gamma reference voltage. The gate-on voltage and the gate-off voltage are supplied to a level shifter 140 and a gate driver 120.

The display panel driving circuit writes the pixel data of the input image to the display pixels P of the display panel 100 under the control of a timing controller 130, and senses a touch input on the display area. The display panel driving circuit includes the data driver 110, the gate driver 120, and a touch sensor driver 160, and the like. The display panel driving circuit can further include a demultiplexer array 112 disposed between the data driver 110 and the data lines DL.

The data driver 110 receives pixel data of an input image received as a digital signal from the timing controller 130 and outputs a data voltage. The data driver 110 outputs the data voltage by converting the pixel data of the input image into a gamma compensation voltage using a digital-to-analog converter (DAC). The gamma reference voltage (VGMA) is divided into a gamma compensation voltage for each grayscale through a voltage divider circuit. The gamma compensation voltage for each grayscale is provided to the DAC of the data driver 110. The data voltage is output from each channel of the data driver 110 through an output buffer.

The demultiplexer array 112 sequentially applies the data voltages output from the channels of the data driver 110 to the data lines DL using a plurality of demultiplexers (DEMUXs). The demultiplexer can include a plurality of switch elements disposed on the display panel 100. When the demultiplexer is disposed between output terminals of the data driver 110 and the data lines DL, the number of channels of the data driver 110 can be reduced. The demultiplexer array 112 can be omitted.

The gate driver 120 can be formed in a circuit layer CIR on the display panel 100 together with a TFT array and lines of the pixel array. The gate driver 120 can be disposed on a bezel area BZ, which is a non-display area of the display panel 100, or can be disposed by being distributed in the pixel array in which an input image is reproduced.

The gate driver 120 can be disposed in the bezel areas BZ on both sides of the display panel 100 with the display area of the display panel 100 therebetween, and can supply gate pulses to both sides of the gate lines GL using a double feeding method. In another embodiment, the gate driver 120 can be disposed on one side of the left and right bezels of the display panel 100 to supply the gate signals to the gate lines GL using a single feeding method. The gate driver 120 sequentially outputs pulses of the gate signals to the gate lines under control of the timing controller 130. The gate driver 120 can sequentially supply the gate signal to the gate lines GL by shifting the gate signal using a shift register.

The data driver 110 and the touch sensor driver 160 can be integrated into one driver integrated circuit (IC). In a mobile terminal or a wearable terminal, the timing controller 130, the power supply 150, the level shifter 140, the data driver 110, the touch sensor driver 160, and the like can be integrated into one driver IC.

The touch sensor driver 160 includes an analog circuit unit, a digital circuit unit, and a touch coordinate calculation unit. Drive signals are applied to drive lines to charge the capacitance formed between lines of a touch sensor layer. The analog circuit unit senses changes in capacitance before and after a touch input by amplifying voltages of sensing lines using an amplifier and an integrator. The digital circuit unit converts analog touch sensing values output from the analog circuit unit into digital data using an analog-to-digital converter (ADC) to output touch raw data, and compares the touch raw data with a predetermined reference value. The touch coordinate calculation unit calculates coordinate values for the touch raw data that exceeds the reference value, and outputs touch data including coordinate information for each touch input. The touch data output from the touch sensor driver 160 is transmitted to the host system 200. The higher a frequency at which the touch data is transmitted, e.g., a touch report rate, the faster the host system 200 can recognize a touch input. Accordingly, the higher the touch report rate, the higher touch input sensitivity.

The timing controller 130 receives digital video data of the input image and a timing signal synchronized with the digital video data from the host system 200. The timing signal can include a vertical synchronization signal Vsync, a horizontal synchronization signal Hsync, a clock CLK, a data enable signal DE, and the like. The vertical synchronization signal Vsync and the horizontal synchronization signal Hsync can be omitted since a vertical period (or a frame period) and a horizontal period can be obtained by a method of counting the data enable signal DE. The data enable signal DE has a period of one horizontal period 1H.

The timing controller 130 can generate a data timing control signal for controlling an operation timing of the data driver 110, a multiplexer (MUX) control signal for controlling an operation timing of the demultiplexer array 112, and a gate timing control signal for controlling an operation timing of the gate driver 120 based on the timing signal received from the host system 200. The timing controller 130 controls the operation timing of the display panel driving circuit to synchronize the data driver 110, the demultiplexer array 112, and the gate driver 120 therewith.

The gate timing control signal generated by the timing controller 130 can be input to the shift register of the gate driver 120 through the level shifter 140. The level shifter 140 can receive the gate timing control signal and generate and provide a start pulse and a shift clock to the gate driver 120. The level shifter 140 can increase a swing width of the MUX control signal, which is input from the timing controller 130 and has a digital signal level, to a voltage level between the gate-on voltage and the gate-off voltage, and provide the MUX control signal to the demultiplexer array 112.

The host system 200 can include a main board of any one of a television (TV) system, a navigation system, a personal computer (PC), a vehicle system, a mobile terminal, and a wearable terminal. The host system 200 can scale an image signal from a video source to match the resolution of the display panel 100 and transmit a resultant image signal and the timing signal to the timing controller 130.

In the mobile system, the host system 200 can be implemented as an application processor (AP). The host system 200 can transmit the pixel data of the input image to the driver IC D-IC through a mobile industry processor interface (MIPI). The host system 200 can be connected to the driver IC through a flexible printed circuit, for example, a flexible printed circuit (FPC). The driver IC can be attached on the display panel 100 in a chip on glass (COG) process.

The host system 200 can execute an application program corresponding to a coordinate value at which a touch input is detected, in response to the touch data received from the touch sensor driver 160.

In an image capturing mode, the host system 200 converts data received from an optical sensor into graphic image data. In a facial recognition mode, the host system 200 compares feature point data received from the optical sensor with pre-stored facial data of a user to perform user authentication. In a touch recognition mode, the host system 200 determines whether the touch input is present and identifies a location of the touch input based on the touch data received from the touch sensor driver 160.

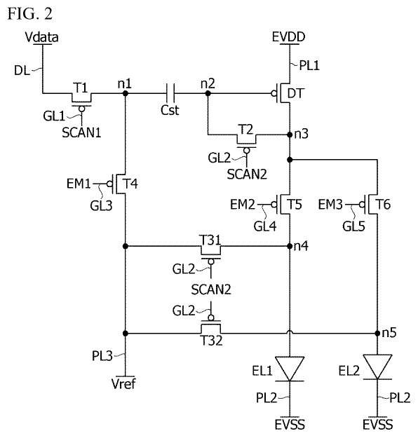

FIG. 2 is a circuit diagram illustrating a pixel circuit according to one embodiment of the present specification. The pixel circuit illustrated in FIG. 2 illustrates an arbitrary sub-pixel circuit disposed in an Nth pixel line (e.g., where N is a natural number). The pixel circuit can include an internal compensation circuit that senses a threshold voltage Vth of a driving element DT and compensates for a data voltage Vdata by the threshold voltage Vth of the driving element DT. The pixel circuit of the present invention is not limited to that in FIG. 2.

Referring to FIG. 2, the pixel circuit includes a first light-emitting element EL1 configured to emit light in a first mode PMODE (e.g., privacy mode with a narrow viewing angle), a second light-emitting element EL2 configured to emit light in a second mode SMODE (e.g., sharing mode with a wide viewing angle), a driving element DT configured to drive the first and second light-emitting elements EL1 and EL2, a plurality of switch elements T1 to T6, and a capacitor Cst. The driving element DT and the switch elements T1 to T6 can be implemented as p-channel transistors, but embodiments of the present disclosure are not limited thereto.

The first light-emitting element EL1 and the second light-emitting element EL2 can be disposed in a structure of main-redundancy elements in which both elements emit light of the same wavelength. For example, the first light-emitting element EL1 can be defined as a main element, and the second light-emitting element EL2 can be defined as a redundancy element.

By arranging the light-emitting element as a redundancy element, the redundancy element can be used for various purposes, such as serving as a backup against LED transfer defects, depending on the design of the display panel. For example, when no defect occurs in the main element, the first light-emitting element EL1, which is the main element, can be driven. For example, when a defect occurs in the main element, the second light-emitting element EL2, which is the redundancy element, can be driven.

However, this is merely an example, and depending on the design of the display device, the first light-emitting element EL1, which is the main element, and the second light-emitting element EL2, which is the redundancy element, can be selectively driven for various purposes.

For example, in the display device according to the embodiment of the present invention, the first mode PMODE (e.g., a privacy mode for a narrow viewing angle mode) is defined as a mode in which light emitted from the display device is limited to a certain angular range, and the second mode SMODE (e.g., a sharing mode for a wide viewing angle mode) is defined as a mode in which the light is emitted beyond a certain angular range from the display device.

The display device according to one embodiment of the present specification can be dynamically switched to or between the first mode PMODE and/or the second mode SMODE based on a user's condition or operation. In this situation, during operation in the first mode PMODE, the main element, e.g., the first light-emitting element EL1, can be driven, and during operation in the second mode SMODE, the redundancy element, e.g., the second light-emitting element EL2, can be driven.

The pixel circuit is connected to a data line DL through which the data voltage Vdata is applied, and gate lines GL1 to GL6 through which gate signals SCAN1, SCAN2, EM1, Em2, and Em3 Are Applied.

The pixel circuit is connected to power nodes, to which DC voltages (or constant voltages) are applied, such as a first constant voltage node PL1 to which a pixel driving voltage EVDD is applied, a second constant voltage node PL2 to which a pixel base voltage EVSS is applied, and a third constant voltage node PL3 to which a reference voltage Vref is applied. Power lines to which the constant voltage nodes are connected can be commonly connected to all the pixels on the display panel 100.

The pixel driving voltage EVDD is set to a voltage, which is higher than the maximum voltage of the data voltage Vdata and allows the driving element DT to operate in a saturation region. The pixel driving voltage EVDD is a voltage higher than the pixel base voltage EVSS. The reference voltage Vref can be set to a voltage that is lower than the pixel driving voltage EVDD and higher than the pixel base voltage EVSS. A gate-on voltage VGL can be set to a voltage higher than the pixel driving voltage EVDD and a gate-off voltage VGH can be set to a voltage lower than the pixel base voltage EVSS. For example, EVDD=13[V], EVSS=0[V], Vref=2.5[V], VGH=14[V], and VGL=−9[V], but embodiments of the present disclosure are not limited thereto.

The gate signals SCAN1, SCAN2, EM1, EM2, and EM3 include pulses that swings between the gate-on voltage VGL and the gate-off voltage VGH.

The driving element DT drives the first and second light-emitting elements EL1 and EL2 by generating a current according to a gate-source voltage Vgs. The driving element DT includes a first electrode connected to the first constant voltage node PL1 to which the pixel driving voltage EVDD is applied, a gate electrode connected to a second node n2, and a second electrode connected to a third node n3.

The first and second light-emitting elements EL1 and EL2 can be implemented as organic light-emitting diodes (OLEDs). Each of the light-emitting elements EL1 and EL2 includes an anode, a cathode, and an organic compound layer formed between the anode and the cathode. The anode of the first light-emitting element EL1 is connected to a fourth node n4, and the cathode thereof is connected to the second constant voltage node PL2 to which the pixel base voltage EVSS is applied. The anode of the second light-emitting element EL2 is connected to a fifth node n5, and the cathode thereof is connected to the second constant voltage node PL2. The organic compound layer can include a hole injection layer HIL, a hole transport layer HTL, an emission layer, an electron transport layer ETL, and an electron injection layer EIL, but embodiments of the present disclosure are not limited thereto. Each of the light-emitting elements EL1 and EL2 can be implemented in a tandem structure in which a plurality of emission layers are stacked. The light-emitting elements EL1 and EL2 of the tandem structure can improve the luminance and lifetime of the pixel.

The capacitor Cst is connected between a first node n1 and the second node n2. In a sensing period SEN, the data voltage Vdata compensated by the threshold voltage Vth of the driving element DT is stored in the capacitor Cst. The capacitor Cst maintains the gate-source voltage Vgs of the driving element DT during an emission period EMIS.

A first switch element T1 is connected between the data line DL and the first node n1. The first switch element T1 is turned on according to a gate-on voltage VGL of a first gate signal SCAN1 to apply the data voltage Vdata of pixel data to the capacitor Cst. The first switch element T1 includes a first electrode connected to the data line DL, a gate electrode connected to a first gate line GL1 through which the first gate signal SCAN1 is applied, and a second electrode connected to the first node n1.

A second switch element T2 is connected between the second node n2 and the third node n3. The second switch element T2 is turned on according to a gate-on voltage VGL of a second gate signal SCAN2 to connect the gate electrode and second electrode of the driving element DT. The second switch element T2 includes a first electrode connected to the second node n2, a gate electrode connected to a second gate line GL2 through which the second gate signal SCAN2 is applied, and a second electrode connected to the third node n3.

A 3-1 switch element T31 is connected between the fourth node n4 and the third constant voltage node PL3. The 3-1 switch element T31 is turned on according to the gate-on voltage VGL of the second gate signal SCAN2 to connect the fourth node n4 to the third constant voltage node PL3 to which the reference voltage Vref is applied. The 3-1 switch element T31 includes a first electrode connected to the third constant voltage node PL3, a gate electrode connected to the second gate line GL2, and a second electrode connected to the fourth node n4.

A 3-2 switch element T32 is connected between the fifth node n5 and the third constant voltage node PL3. The 3-2 switch element T32 is turned on according to the gate-on voltage VGL of the second gate signal SCAN2 to connect the fifth node n5 to the third constant voltage node PL3 to which the reference voltage Vref is applied. The 3-2 switch element T32 includes a first electrode connected to the third constant voltage node PL3, a gate electrode connected to the second gate line GL2, and a second electrode connected to the fifth node n5.

A fourth switch element T4 is connected between the first node n1 and the third constant voltage node PL3. The fourth switch element T4 is turned on according to a gate-on voltage VGL of a third gate signal EM1 to connect the first node n1 to the third constant voltage node PL3. The fourth switch element T4 includes a first electrode connected to the first node n1, a gate electrode connected to a third gate line GL3 through which the third gate signal EM1 is applied, and a second electrode connected to the third constant voltage node PL3.

A fifth switch element T5 is connected between the third node n3 and the fourth node n4. The fifth switch element T5 is turned on according to a gate-on voltage VGL of a fourth gate signal EM2 to connect the third node n3 to the fourth node n4. The fifth switch element T5 includes a first electrode connected to the third node n3, a gate electrode connected to a fourth gate line GL4 through which the fourth gate signal EM2 is applied, and a second electrode connected to the fourth node n4.

A sixth switch element T6 is connected between the third node n3 and the fifth node n5. The sixth switch element T6 is turned on according to a gate-on voltage VGL of a fifth gate signal EM3 to connect the third node n3 to the fifth node n5. The sixth switch element T6 includes a first electrode connected to the third node n3, a gate electrode connected to a fifth gate line GL5 through which the fifth gate signal EM3 is applied, and a second electrode connected to the fifth node n5.

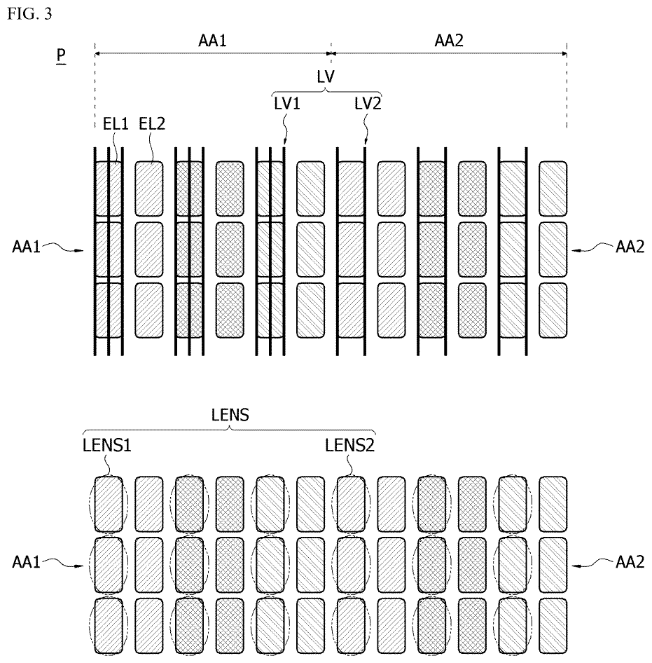

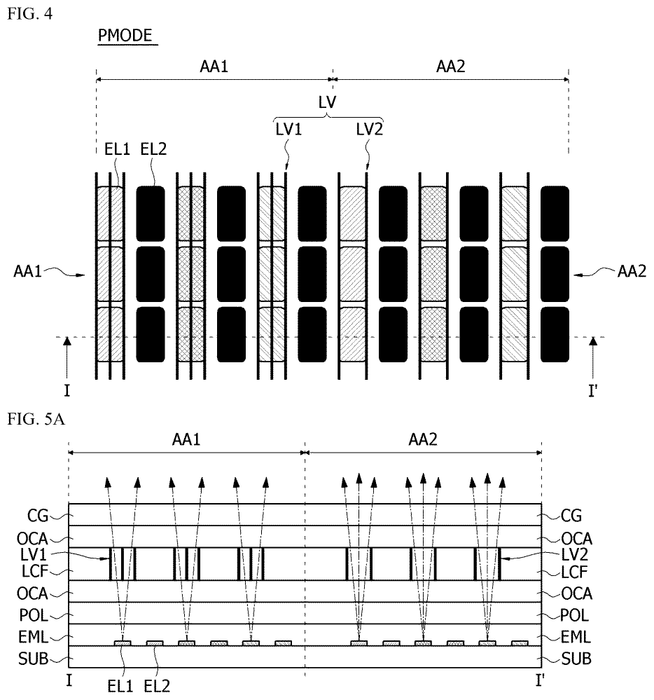

FIG. 3 is an enlarged plan view of region P in FIG. 1 according to one embodiment of the present specification, and FIG. 4 is an enlarged plan view of region P in FIG. 1 when the first mode is driven according to one embodiment of the present specification.

Referring to FIGS. 3 and 4, a light control member can be disposed above the first light-emitting element EL1 to restrict a viewing angle when the first mode PMODE is driven. When the display device operates in the first mode PMODE, as shown in FIG. 4, the first light-emitting element EL1, over which the light control member is disposed, can be turned on to emit light, while the second light-emitting element EL2 can be turned off.

A partition walls LV are disposed over the first light-emitting elements EL1 as light control members. The partition walls LV can include a first partition walls LV1 disposed in the first display area AA1 and a second partition walls LV2 disposed in the second display area AA2. The densities of the first partition walls LV1 disposed in the first display area AA1 and the second partition walls LV2 disposed in the second display area AA2 can be different. For example, as shown in FIG. 3, the first partition walls LV1 disposed in the first display area AA1 can be disposed at a higher density than the second partition walls LV2 disposed in the second display area AA2.

Since the first partition walls LV1 disposed in the first display area AA1 are disposed with a higher density than the second partition walls LV2 disposed in the second display area AA2, when the display device operates in the first mode PMODE, light emitted from the first display area AA1 can have a narrower viewing angle than light emitted from the second display area AA2. For example, since the partition walls are closer together in the first display area, it can produce a narrower viewing angle than the second display area during the first mode of operation (e.g., privacy mode). In other words, even when operating in the first mode of operation (e.g., privacy mode) different parts of the screen can have different viewing angles, e.g., an outer area of the screen can have a narrow viewing angle during the first mode of operation (e.g., privacy mode) while a center of the screen or a portion directly in front of a driver can have an even narrower viewing angle during the first mode of operation (e.g., privacy mode). In this way, the user (e.g., the driver, or the passenger) can still properly see portions of the screen that are located a little farther away from his or her center area of focus even when operating in the privacy mode.

According to another embodiment of the present specification, lenses LENS can be disposed on the first light-emitting element EL1 as the light control members. The lenses LENS can include first lenses LENS1 disposed in the first display area AA1 and second lenses LENS2 disposed in the second display area AA2.

The lens LENS can be a hemispherical lens that is thicker at the center and thinner toward the edge. The lens LENS can condense light emitted from the first light-emitting element EL1 in the first mode PMODE to narrow vertical and horizontal viewing angles of the first light-emitting element EL1. According to another embodiment, the lens LENS can have a rounded rectangular or semi-cylindrical shape, etc.

When the lens LENS are disposed as the light control member on the first light-emitting element EL1, the first lens LENS1 disposed in the first display area AA1 and the second lens LENS2 disposed in the second display area AA2 can be disposed to have different sizes. For example, as shown in FIG. 3, the first lens LENS1 disposed in the first display area AA1 can be disposed to be larger in size than the second lens LENS2 disposed in the second display area AA2. The first and second lenses LENS1 and LENS2 can be implemented as transparent media or transparent insulating layer patterns disposed in the display panel 100, but embodiments of the present disclosure are not limited thereto. Also, the some of the figures show that the first lens LENS1 and the second lens LENS2 are arranged in alternating columns, but embodiments are not limited thereto. For example, according to embodiments, the first lens LENS1 and the second lens LENS2, can be arranged in various patterns, such as alternating rows, alternating diagonals, randomly mixed, checker arrangements or checker board style arrangements, grid arrangements, etc. For example, the narrow angle sub-pixels (with light control members) and wide angle sub-pixels can be interleaved in a fine checkerboard or striped pattern across the entire display, which can provide a more uniform appearance.

FIGS. 5A and 5B are cross-sectional views taken along line I-I′ of FIG. 4 according to one embodiment of the present specification.

Referring to FIGS. 5A and 5B, the display panel 100 according to one embodiment of the present specification can include a substrate SUB, a light-emitting element layer EML, a polarizer POL, adhesive layers OCA, a film layer LCF, and a cover glass CG.

The substrate SUB can be formed of an insulating material or a material having flexibility. For example, the substrate SUB can be formed of glass, metal, plastic, or the like, but embodiments of the present disclosure are not limited thereto.

The substrate SUB can include a display area DA and a non-display area NDA. Here, the display area DA and the non-display area NDA are not described only with respect to the substrate SUB, but can be described with respect to the entire display device.

The light-emitting element layer EML can be disposed on the substrate SUB. The light-emitting element layer EML can include light-emitting elements driven by the pixel circuit. Here, the light-emitting element can be implemented as an organic light-emitting diode (OLED). The OLED can include an organic compound layer formed between an anode and a cathode. The organic compound layer can include a hole injection layer HIL, a hole transport layer HTL, an emission layer an electron transport layer ETL, and an electron injection layer EIL, but embodiments of the present disclosure are not limited thereto. When a voltage is applied to the anode and the cathode of the OLED, holes passing through the hole transport layer HTL and electrons passing through the electron transport layer ETL move to the emission layer to create excitons, and thus visible light can be emitted from the emission layer.

Also, a circuit layer including a circuit for driving the light-emitting element EL can be disposed between the substrate SUB and the light-emitting element layer EML. The circuit layer can include a pixel circuit connected to lines such as data lines, gate lines, power lines, and the like, a gate driver connected to the gate lines, and the like. In addition, the circuit layer can include circuit elements such as transistors implemented as TFTs, capacitors, and the like. For example, the lines and circuit elements of the circuit layer can be implemented with a plurality of insulating layers, two or more metal layers separated from each other with the insulating layers therebetween, and an active layer including a semiconductor material.

The light-emitting element layer EML can be covered by a protective film. The protective film can have a structure in which organic films and inorganic films are alternately stacked. In this situation, the inorganic films can block the penetration of moisture or oxygen. In addition, the organic films can planarize a surface of the inorganic film. When the organic films and the inorganic films are stacked in multiple layers, the movement path of the moisture or oxygen is increased in length compared with a single layer so that the penetration of moisture/oxygen affecting the light-emitting element layer EML can be effectively blocked.

The polarizer POL can be disposed on the light-emitting element layer EML. The polarizer POL can suppress reflection of external light on the display area AA of the substrate SUB. The polarizer POL can polarize incident external light in a specific direction and can prevent reflected light from being re-emitted to the outside of the display device. The polarizer POL can be omitted according to an embodiment, and the embodiments of the present specification are not limited thereto.

The film layer LCF can be disposed on the polarizer POL. The film layer LCF is an optical functional film that allows incident light to be emitted only within a certain angular range. The film layer LCF can include a transparent organic material. For example, the film layer LCF can include at least one of organic materials such as acrylic resin, polyvinyl chloride (PVC), polyethylene terephthalate (PET), polyacrylate, polyurethane, polycarbonate, and polypropylene.

A light control member can be disposed in the film layer LCF disposed above the first light-emitting element EL1. The light control member can include a partition wall LV or a lens.

The partition wall LV can include a first partition wall LV1 disposed in the first display area AA1 and a second partition wall LV2 disposed in the second display area AA2. The partition walls LV1 and LV2 can include the same material and can be simultaneously formed by the same process. The partition walls LV1 and LV2 can include a metal black matrix material, such as chromium (Cr) or Cr/chromium oxide (CrOx). Alternatively, the partition walls LV1 and LV2 can include a resin black matrix material, in which a Cr-based metal material or a carbon-based organic material is mixed into a photoresist that includes a photoinitiator, a binder resin, a polymer monomer, a solvent, and the like. In addition, the partition wall LV can include black matrix materials such as an organic material including carbon black, a black matrix resin material using mixed metal oxides, or a black matrix resin using an inorganic material. The partition wall LV can be formed using a photolithography process or a lift-off process, depending on the material used.

The adhesive layers OCA can be disposed above and below the film layer LCF. The adhesive layers OCA allow the film layer LCF to be bonded to the underlying polarizer POL and the overlying cover glass CG. The adhesive layer OCA can be formed of a material having an adhesive property, and can be a thermosetting or naturally curing adhesive. For example, the adhesive layer OCA can be formed of an optical clear adhesive (OCA), a pressure-sensitive adhesive (PSA), or the like, but embodiments of the present disclosure are not limited thereto.

As shown in FIG. 5B, the lenses LENS can be disposed above the first light-emitting element EL1 instead of the partition walls LV.

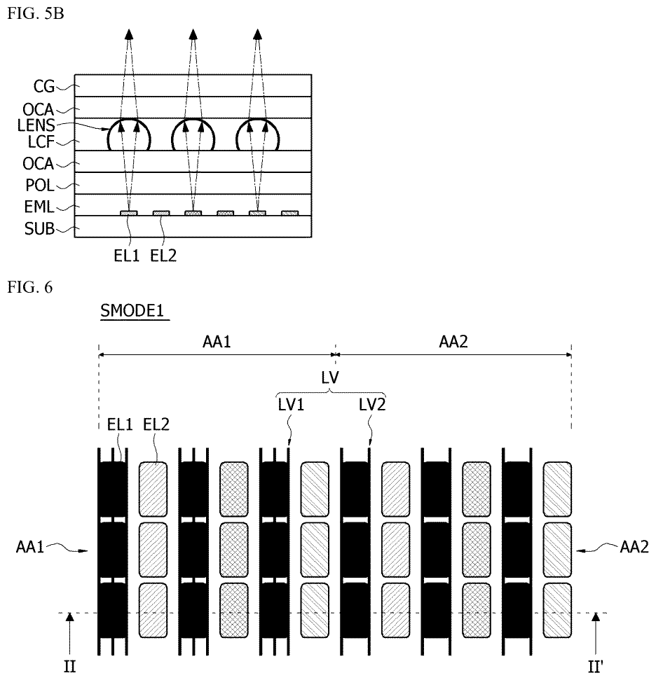

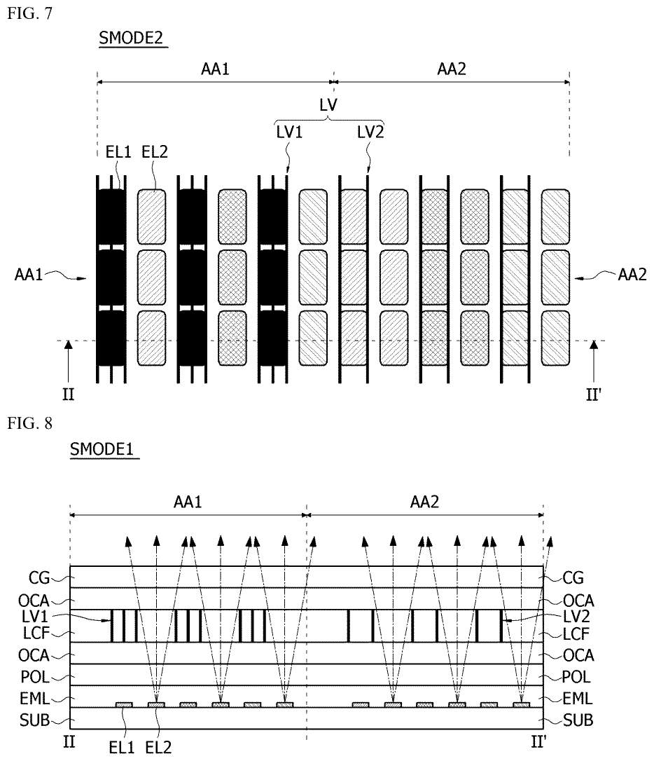

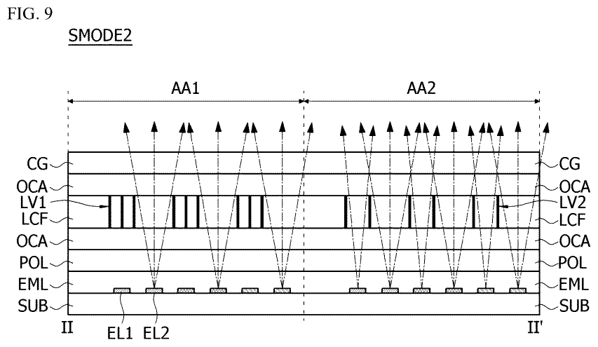

FIG. 6 is an enlarged plan view of region P of FIG. 1 when a 2-1 mode (e.g., sharing mode) is driven according to one embodiment of the present specification. FIG. 7 is an enlarged plan view of region P of FIG. 1 when a 2-2 mode (e.g., sharing mode with increased brightness) is driven according to another embodiment of the present specification. FIGS. 8 and 9 are cross-sectional views taken along line II-II′ of FIG. 6 according to one embodiment of the present specification.

Referring to FIG. 6, the display device according to the embodiment of the present specification can operate in the second mode SMODE in which light having a viewing angle different from that in the first mode PMODE, which is a narrow viewing angle mode, is emitted. The second mode SMODE can include a 2-1 mode SMODE1 (e.g., sharing mode) and a 2-2 mode SMODE2 (e.g., extra bright sharing mode). The second mode SMODE can also be referred to as a wide viewing angle mode.

Referring to FIGS. 6 and 8, in the 2-1 mode SMODE1, the second light-emitting element EL2, in which a light control member such as the partition wall LV is not disposed, can be turned on to emit light, and the first light-emitting element EL1, in which a light control member such as the partition wall LV is disposed, can be turned off.

In the 2-1 mode SMODE1, since the second light-emitting element EL2, in which the light control member such as the partition wall LV is not disposed, is turned on to emit light, the light can be emitted at a wider viewing angle than in the first mode PMODE, in which the first light-emitting element EL1, with the light control member such as the partition wall LV disposed thereabove, is turned on to emit light.

Referring to FIGS. 7 and 9, the display device according to the present specification can operate in the 2-2 mode SMODE2, in which both the first light-emitting element EL1 and the second light-emitting element EL2 emit light, when higher luminance is desired in the second mode SMODE (e.g., in the situation of a sunny day or bright room, etc.).

Since the display device operates in the 2-2 mode SMODE2 in which both the first light-emitting element EL1 and the second light-emitting element EL2 emit light, the light can be emitted with a target luminance using relatively less power compared to the first mode PMODE or the 2-1 mode SMODE1, in which only one of the first and second light-emitting elements EL1 and EL2 emits light.

For example, the first light-emitting element EL1 disposed in the second display area AA2 and the second light-emitting element EL2 disposed in the display area AA can be turned on to emit light. However, the present invention is not limited thereto, and the first light-emitting element EL1 disposed in the first display area AA1 can also be turned on, such that all the light-emitting elements EL1 and EL2 emit light.

A display device according to the present specification includes a display area including a first display area and a second display area, a light-emitting element layer including a first light-emitting element and a second light-emitting element, which are disposed in the display area, and a film layer disposed on the light-emitting element layer, in which the film layer includes a light control member disposed above the first light-emitting element, the first light-emitting element emits light at a first viewing angle in a first mode, and the second light-emitting element emits light at a second viewing angle that is wider than the first viewing angle in a second mode.

The display device according to the present specification can further include a polarizer disposed on the light-emitting element layer, and a cover glass disposed on the polarizer, in which the film layer is disposed between the polarizer and the cover glass.

The light control member of the display device according to the present specification can further include a partition wall configured to block the light emitted from the light-emitting element, and a lens configured to refract the light emitted from the light-emitting element.

Some embodiments show partition walls or lens being able to narrow the viewing angle to provide the privacy mode, but embodiments are not limited thereto. For example, according to another embodiment, liquid crystal shutters can be used. For example, another alternative embodiment, the light control member can include an electronically controlled liquid crystal layer disposed over the pixels of the display panel. This liquid crystal layer can be configured to switch between at least a first, substantially transparent state and a second, substantially opaque state in response to an applied voltage. When operating in a wide viewing angle mode, no voltage is applied, and the transparent layer can allow light to pass without obstruction. To engage a narrow viewing angle mode, a voltage can be selectively applied to the liquid crystal layer, causing specific regions between pixels to transition to the opaque state. These opaque regions can function as virtual partition walls, which restrict the path of emitted light and thus narrow the viewing angle.

According to another embodiment, either the first light-emitting elements EL1 or the second light-emitting elements EL2 could be configured to emit a different type of light, such as non-visible or infrared (IR) light, e.g., for being viewed with night vision equipment or for interacting with other IR-based sensors such as a camera or a face ID feature, etc.

The partition wall of the display device according to the present specification can include first partition walls disposed in the first display area, and second partition walls disposed in the second display area, and a density of the first partition walls can be higher than a density of the second partition walls. For example, the screen can be divided into different areas where the partition walls can be more densely packed or less densely packed. Also, according to embodiments, the partition walls can be arranged parallel to the data lines or perpendicular to the data lines, or diagonal, etc. Alternatively, other arrangements for the partition walls can be provided, such as cross-hatched, grid screen type of patterns.

In the display device according to the present specification, the first viewing angle of the first light-emitting element disposed in the first display area and the first viewing angle of the first light-emitting element disposed in the second display area can be different from each other.

In the display device according to the present specification, the first viewing angle of the first light-emitting element disposed in the first display area can be narrower than the first viewing angle of the first light-emitting element disposed in the second display area.

The light-emitting elements of the display device according to the present specification can be driven in the first mode or the second mode by receiving a signal from a timing controller.

In the display device according to the present specification, the first light-emitting element can be turned on to emit light in the first mode, and the second light-emitting element can be turned on to emit light in the second mode.

The second light-emitting element of the display device according to the present specification can be disposed as a redundant light-emitting element that emits light having the same wavelength as the first light-emitting element.

According to the present specification, a single screen can be selectively driven in either a wide viewing angle mode or a narrow viewing angle mode by disposing a light control member above only one of light-emitting elements disposed in a redundancy structure.

The effects of the present specification are not limited to the effects mentioned above, and other effects not mentioned can be clearly understood by those skilled in the art to which the technical idea of the present specification pertains from the following description.

While the embodiments of the present invention have been described in detail above with reference to the accompanying drawings, the present invention is not necessarily limited to these embodiments, and various changes and modifications can be made without departing from the technical spirit of the present invention. Accordingly, the embodiments disclosed herein are intended to illustrate and not to limit the technical ideas of the present invention, and the scope of the technical ideas of the present invention is not limited by these embodiments. Accordingly, the above-described embodiments should be understood to be examples and not limiting in any aspect. The scope of the present invention should be construed by the appended claims, and all technical ideas within the scope of their equivalents should be construed as being included in the scope of the present invention.

What is claimed is:

1. A display device comprising:
a display area including a first display area and a second display area;
a light-emitting element layer disposed in the display area, the light-emitting element layer including a first light-emitting element and a second light-emitting element; and
a film layer disposed on the light-emitting element layer,
wherein the film layer includes a light control member disposed above the first light-emitting element,
wherein the first light-emitting element is configured to emit light at a first viewing angle in a first mode, and
wherein the second light-emitting element configured to emit light at a second viewing angle in second mode, the second viewing angle being wider than the first viewing angle.

2. The display device of claim 1, further comprising:
a polarizer disposed on the light-emitting element layer; and
a cover glass disposed on the polarizer,
wherein the film layer is disposed between the polarizer and the cover glass.

3. The display device of claim 1, wherein the light control member further includes a partition wall configured to block the light emitted from at least one of the first light-emitting element and the second light-emitting element, and a lens configured to refract the light emitted from the at least one of the first light-emitting element and the second light-emitting element.

4. The display device of claim 3, wherein the partition wall includes first partition walls disposed in the first display area, and second partition walls disposed in the second display area, and
wherein a density of the first partition walls is higher than a density of the second partition walls.

5. The display device of claim 3, wherein the first viewing angle of the first light-emitting element disposed in the first display area and the first viewing angle of the first light-emitting element disposed in the second display area are different from each other.

6. The display device of claim 3, wherein the first viewing angle of the first light-emitting element disposed in the first display area is narrower than the first viewing angle of the first light-emitting element disposed in the second display area.

7. The display device of claim 1, wherein at least one of the first light-emitting element and the second light-emitting element is configured to be driven in the first mode or the second mode by receiving a signal from a timing controller.

8. The display device of claim 1, wherein the first light-emitting element is configured to be turned on to emit light in the first mode, and
wherein the second light-emitting element is configured to be turned on to emit light in the second mode.

9. The display device of claim 1, wherein the second light-emitting element is configured as a redundant light-emitting element configured to emit light having a same wavelength as the first light-emitting element.

10. A display device, comprising:
a first type of sub-pixel configured to emit light;
a second type of sub-pixel configured to emit light; and
a light directing structure overlapping with the first type of sub-pixel without overlapping with the second type of sub-pixel; and
a controller configured to:
activate the first type of sub-pixel to operate in a narrow viewing angle mode, and
activate the second type of sub-pixel to operate in a wide viewing angle mode with a viewing angle wider than a viewing angle of the narrow viewing angle mode.

11. The display device of claim 10, wherein the light directing structure includes a plurality of partition walls configured to block a portion of the light emitted from the first type of sub-pixel.

12. The display device of claim 11, wherein the display device comprises a first display area and a second display area, and
wherein a density of the plurality of partition walls is greater in the second display area than in the first display area.

13. The display device of claim 11, wherein the plurality of partition walls include a black matrix material.

14. The display device of claim 10, wherein the light directing structure includes one or more lens configured to narrow the light emitted from the first type of sub-pixel.

15. The display device of claim 10, wherein the first type of sub-pixel and the second type of sub-pixel are configured to emit a same color of light.

16. The display device of claim 10, wherein a plurality of the first type of sub-pixel and a plurality of the second type of sub-pixel are arranged in alternating columns.

17. The display device of claim 10, wherein the controller is further configured to activate both the first type of sub-pixel and the second type of sub-pixel simultaneously to operate in a high brightness mode.

18. The display device of claim 10, further comprising a polarizer disposed over the first and second types of sub-pixels,
wherein the light directing structure is positioned between the polarizer and the first type of sub-pixel.

19. The display device of claim 10, wherein the controller is configured to switch between the narrow viewing angle mode and the wide viewing angle mode in response to a selection from a user interface.

20. The display device of claim 10, further comprising a pixel circuit having a driving transistor,
wherein the first type of sub-pixel and the second type of sub-pixel are both electrically coupled to the pixel circuit and configured to selectively receive a driving current from the driving transistor.
